(19) United States
(12) Patent Application Publication
(10) Pub. No.: US 2022/0336194 A1
(43) Pub. Date: Oct. 20, 2022

(54) PLASMA PROCESSING APPARATUS

(71) Applicant: Tokyo Electron Limited, Tokyo (JP)

(72) Inventors: Hiroyuki YOKOHARA, Nirasaki-shi, Yamanashi (JP); Koji MAEDA, Nirasaki-shi, Yamanashi (JP); Yasunobu SUZUKI, Chaska, MN (US); Atsushi SHIMADA, Nirasaki-shi, Yamanashi (JP); Takuya UMISE, Nirasaki-shi, Yamanashi (JP)

(21) Appl. No.: 17/642,992

(22) PCT Filed: Sep. 4, 2020
(86) PCT No.: PCT/JP2020/033592

§ 371 Date: Mar. 15, 2022

(30) Foreign Application Priority Data
Sep. 17, 2019 (JP) 2019-168088
Apr. 20, 2020 (JP) 2020-074978

(51) Int. Cl. H01J 37/32

(52) U.S. Cl. CPC H01J 37/32651; H01J 37/32715; H01J 37/3211; H01J 37/32119; H01J 37/32513; H01J 2237/335; H01J 2237/20214; H01J 2237/2007; H01J 37/3244; H01J 2237/334

(57) ABSTRACT

A plasma processing apparatus for performing plasma processing on a substrate includes: a plasma generator configured to generate plasma in a processing container; a support structure configured to mount the substrate on a tilted mounting surface in the processing container and rotatably support the substrate; a first slit plate made of quartz and provided between the plasma generator and the support structure, the first slit plate having first slits formed in the first slit plate; and a second slit plate made of quartz and provided between the plasma generator and the support structure and below the first slit plate, the second slit plate having second slits formed in the second slit plate, wherein the first slits are staggered from adjacent ones of the second slits in a reverse direction of a tilting direction of the mounting surface.

### TECHNICAL FIELD

The present disclosure relates to a plasma processing apparatus.

### BACKGROUND

For example, Patent Document 1 proposes an apparatus including a bias power supply that applies a pulse-modulated DC voltage as a bias voltage for ion implantation to a support structure to remove by-products formed by etching.

### PRIOR ART DOCUMENTS

### Patent Documents

Patent Document 1: Japanese Laid-open Publication No. 2016-82020

The present disclosure provides some embodiments of a plasma processing apparatus capable of suppressing adhesion of by-products formed by etching to a radio frequency power introduction window while efficiently etching a substrate.

### SUMMARY

According to one embodiment of the present disclosure, there is provided a plasma processing apparatus for performing plasma processing on a substrate, including: a plasma generator configured to generate plasma in a processing container; a support structure configured to mount the substrate on a tilted mounting surface in the processing container and rotatably support the substrate; a first slit plate made of quartz and provided between the plasma generator and the support structure, the first slit plate having first slits formed in the first slit plate; and a second slit plate made of quartz and provided between the plasma generator and the support structure and below the first slit plate, the second slit plate having second slits formed in the second slit plate, wherein the first slits are staggered from adjacent ones of the second slits in a reverse direction of a tilting direction of the mounting surface.

According to the present disclosure, it is possible to suppress adhesion of by-products formed by etching to a radio frequency power introduction window while efficiently etching a substrate.

### BRIEF DESCRIPTION OF DRAWINGS

FIG. 1 is a cross-sectional view schematically showing an example of a tilt precleaning apparatus according to an embodiment.

FIG. 2 is a diagram showing an example of an internal structure of a container according to an embodiment.

FIG. 3 is a diagram for explaining a support structure according to an embodiment.

FIG. 4 is a cross-sectional view taken along line A-A in FIG. 1.

FIG. 5 is a diagram showing an example of a structure for holding a shield plate according to an embodiment.

FIG. 6 is a diagram showing an example of a slit position of a slit plate according to an embodiment.

FIG. 7 is a diagram for explaining positions of slits and movement of ions and deposits according to an embodiment.

FIG. 8A is a diagram showing an example of a simulation for optimizing positions of slits according to an embodiment.

FIG. 8B is a diagram showing another example of a simulation for optimizing positions of slits according to an embodiment.

FIG. 9 is a diagram showing an example of a simulation result for optimizing masking of slits according to a modification of the embodiment.

### DETAILED DESCRIPTION

Hereinafter, embodiments for carrying out the present disclosure will be described with reference to the drawings. In each drawing, the same components may be designated by like reference numerals and duplicate explanations thereof may be omitted.

### [Tilt Precleaning Apparatus]

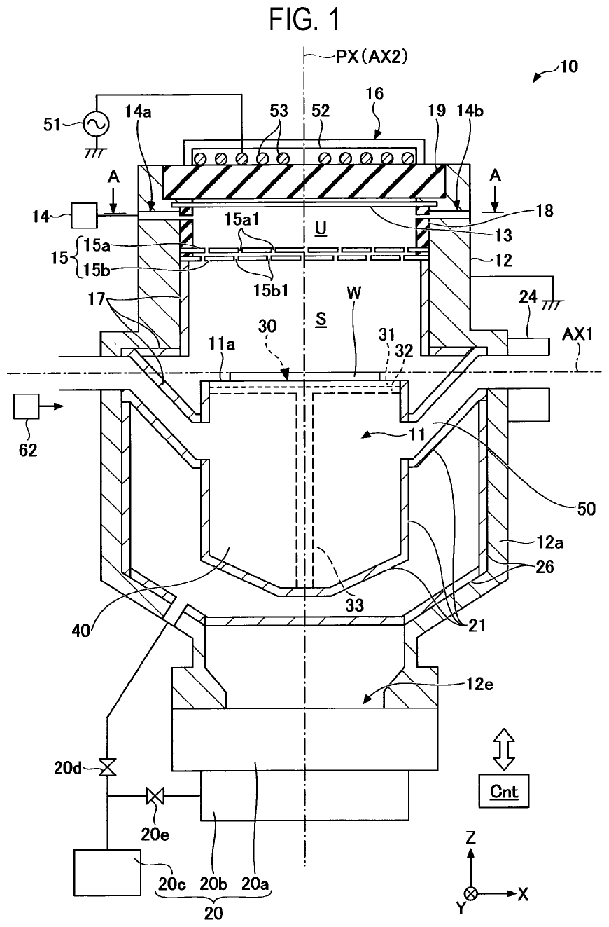

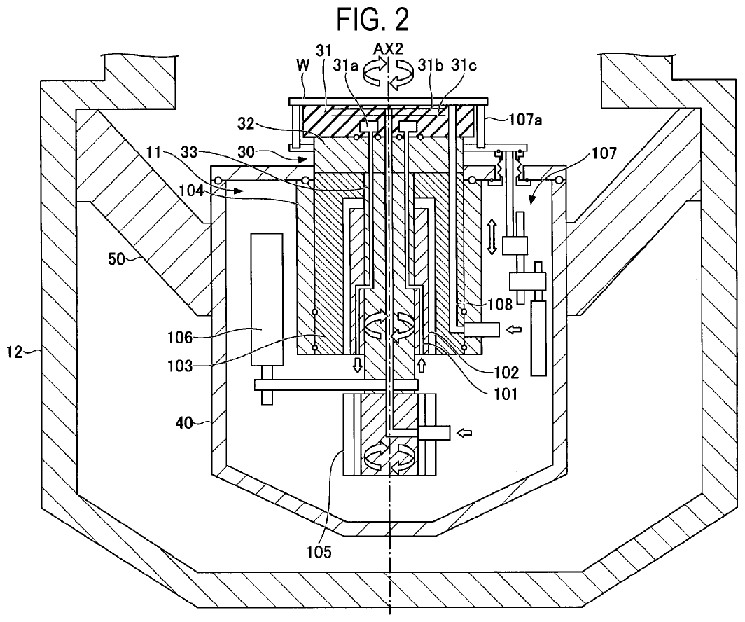

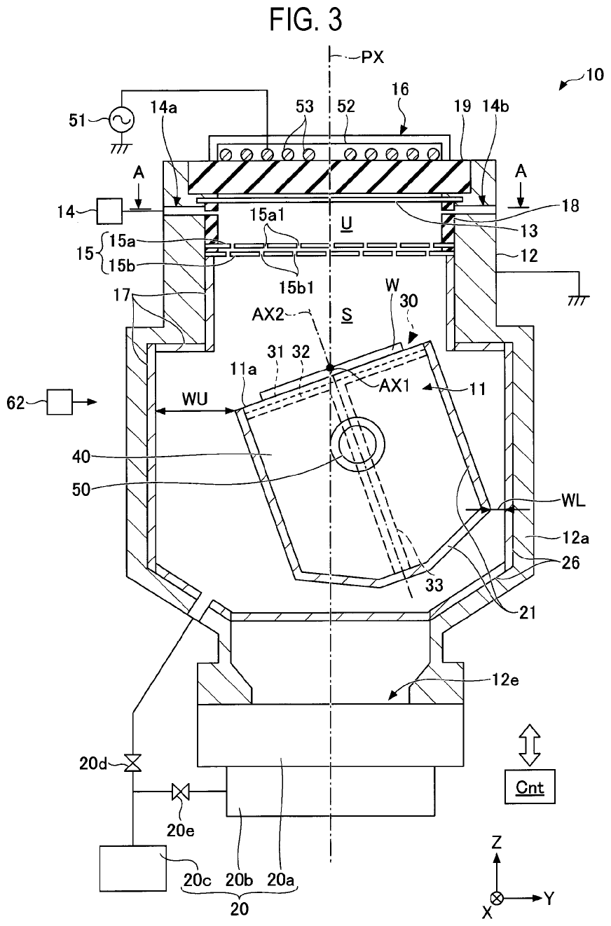

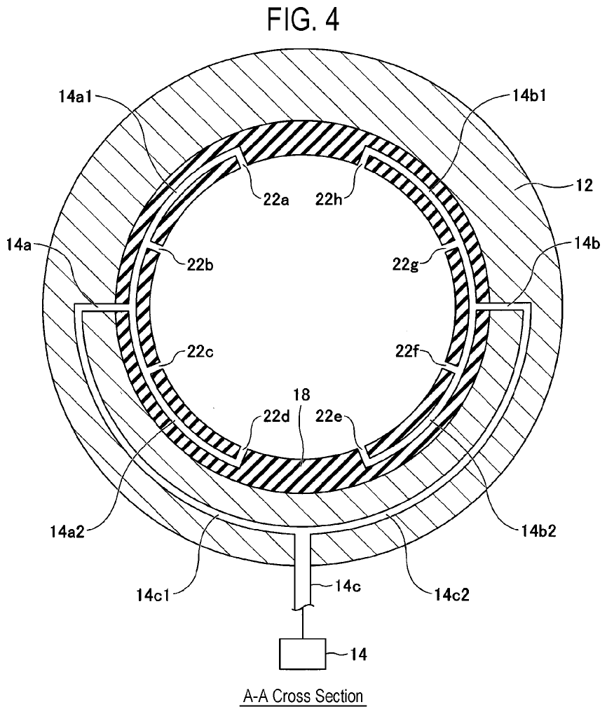

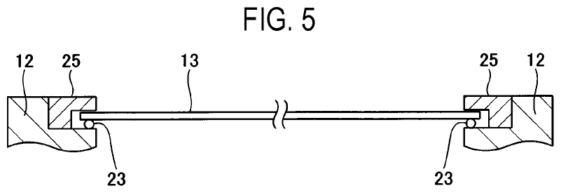

First, a tilt precleaning apparatus 10 according to an embodiment will be described with reference to FIGS. 1 to 5. FIG. 1 is a cross-sectional view schematically showing an example of a tilt precleaning apparatus 10 according to an embodiment. FIG. 2 is a diagram showing an example of an internal structure of a container 40 according to an embodiment. FIG. 3 is a diagram for explaining a support structure 11 according to an embodiment. FIG. 4 is a cross-sectional view taken along line A-A in FIG. 1. FIG. 5 is a diagram showing an example of a structure for holding a shield plate 13 according to an embodiment.

FIGS. 1 and 3 show the tilt precleaning apparatus 10 and cutouts of a processing container 12 along one plane including an axis PX extending in a vertical direction. The tilt precleaning apparatus 10 is an example of a plasma processing apparatus that performs plasma processing on a substrate W. FIG. 1 shows the tilt precleaning apparatus 10 in a state where the support structure 11 is not tilted, and FIG. 3 shows the tilt precleaning apparatus 10 in a state where the support structure 11 is tilted. The support structure 11 mounts the substrate W on a tilted mounting surface 11a in the processing container 12 and rotatably supports the substrate W.

The tilt precleaning apparatus 10 includes the support structure 11, the processing container 12, a gas supply 14, an ICP source unit 16, an exhaust system 20, a bias power supply 62, and a controller Cnt. The processing container 12 has a substantially cylindrical shape and is made of aluminum. In one embodiment, a central axis of the processing container 12 coincides with the axis PX. The processing container 12 provides a space S for performing plasma processing on the substrate W such as a wafer or the like.

In one embodiment, the processing container 12 has a substantially constant width in an intermediate portion 12a in a height direction, i.e., a portion accommodating the support structure 11. Further, the processing container 12 has a tapered shape such that a width thereof gradually narrows from a lower end of the intermediate portion toward a bottom. Further, the bottom of the processing container 12 provides an exhaust port 12e which is formed axially symmetrically with respect to the axis PX.

The support structure 11 is provided in the processing container 12. The support structure 11 attracts and holds the substrate W by an electrostatic chuck 31. The support structure 11 is rotatable about a first axis AX1 orthogonal to the axis PX. The support structure 11 can be tilted with respect to the axis PX by rotation of an inclined shaft part 50 about the first axis AX1. In order to tilt the support structure 11, the tilt precleaning apparatus 10 has a drive device 24. The drive device 24 is provided outside the processing container 12 to generate a driving force for rotating the support structure 11 about the first axis AX1. Further, the support structure 11 is configured to rotate the substrate W about a second axis AX2 orthogonal to the first axis AX1. When the support structure 11 is not tilted, the second axis AX2 coincides with the axis PX as shown in FIG. 1. On the other hand, when the support structure 11 is tilted, the second axis AX2 is inclined with respect to the axis PX as shown in FIG. 3. The details of the support structure 11 will be described later.

The exhaust system 20 is configured to depressurize an internal space of the processing container 12 to a high vacuum degree of, for example, 10⁻⁸ Torr to 10⁻⁹ Torr (1.33×10⁻⁶ Pa to 1.33×10⁻⁷ Pa). In one embodiment, the exhaust system 20 includes an automatic pressure controller 20a, a cryopump or turbo molecular pump 20b, and a dry pump 20c. The turbo molecular pump 20b is provided on a downstream side of the automatic pressure controller 20a. The dry pump 20c is directly connected to the internal space of the processing container 12 via a valve 20d. In addition, the dry pump 20c is provided on a downstream side of the turbo molecular pump 20b via a valve 20e.

The exhaust system 20 including the automatic pressure controller 20a and the turbo molecular pump 20b is attached to the bottom of the processing container 12. Further, the exhaust system 20 including the automatic pressure controller 20a and the turbo molecular pump 20b is provided directly below the support structure 11. Thus, it is possible for the tilt precleaning apparatus 10 to form a uniform exhaust flow from a periphery of the support structure 11 to the exhaust system 20. Therefore, it is possible to achieve efficient exhaust. Further, it is possible to uniformly diffuse plasma generated in the processing container 12.

In one embodiment, a shield 17 is detachably provided on an upper side surface of an inner wall of the processing container 12 in the space S, and a shield 26 is detachably provided on a lower side surface and the bottom surface of the processing container 12. In addition, a shield 21 is detachably provided on a wall surface other than the mounting surface 11a of the support structure 11 and an outer peripheral surface of the inclined shaft part 50. The shields 17, 21, and 26 prevent by-products (hereinafter also referred to as “deposits”) generated by etching from adhering to the processing container 12. The shields 17, 21, and 26 are formed, for example, by blasting a surface of a base material made of aluminum or additionally forming an aluminum sprayed film. The shield 26 is divided into a plurality of pieces to form a labyrinth structure, and a gas is guided to the exhaust system 20 through a gap of the labyrinth structure. The shields 17, 21, and 26 are replaced as appropriate.

An opening is formed in a ceiling of the processing container 12. The opening is closed by a dielectric window 19. The dielectric window 19 is a plate-like body and is made of quartz glass or ceramics.

The gas supply 14 supplies a processing gas into the processing container 12 from flow paths 14a and 14b. The details of the gas supply 14 will be described later with reference to FIG. 4.

The ICP (Inductively Coupled Plasma) source unit 16 excites the processing gas supplied into the processing container 12. In one embodiment, the ICP source unit 16 is provided on the dielectric window 19 in the ceiling of the processing container 12. Further, in one embodiment, a central axis of the ICP source unit 16 coincides with the axis PX. A space of the ICP source unit 16 above the dielectric window 19 is an atmospheric space, and a space inside the processing container 12 below the dielectric window 19 is a vacuum space.

The ICP source unit 16 includes a radio frequency antenna 53 and a shield 52. The radio frequency antenna 53 is covered with the shield 52. The radio frequency antenna 53 is made of a conductor such as copper, aluminum, stainless steel, or the like, and extends spirally around the axis PX. A radio frequency power source 51 is connected to the radio frequency antenna 53. The radio frequency power source 51 is a radio frequency power source for plasma generation.

When a radio frequency power of a predetermined frequency is supplied to the radio frequency antenna 53 from the radio frequency power source 51, the radio frequency power passes through the dielectric window 19 to form an induced magnetic field in the processing container 12. The processing gas introduced into the processing container 12 is excited by the induced magnetic field. As a result, donut-shaped plasma is generated above the substrate W. Radicals and ions are generated from the processing gas by the plasma. The frequency of the radio frequency power supplied from the radio frequency power source 51 may be 13.56 MHz, 27 MHz, 40 MHz, or 60 MHz.

A shield plate 13 is arranged below the dielectric window 19 in the processing container 12 and above the positions of the flow paths 14a and 14b. The shield plate 13 is a thin film made of quartz and is provided in a vicinity of the dielectric window 19 to prevent the by-products generated by etching from flying from the substrate W and adhering to the dielectric window 19.

The bias power supply 62 is configured to apply a radio frequency bias power for implanting ions into the substrate W to the support structure 11. The radio frequency power source 51, the radio frequency antenna 53, the dielectric window 19, and the gas supply 14 function as a plasma generator that generates plasma in a plasma generation space U.

A slit plate 15 is provided between the dielectric window 19 and the support structure 11 and below the shield plate 13. The slit plate 15 includes a quartz slit plate 15a having a plurality of slits 15a1 formed therein, and a quartz slit plate 15b disposed below the slit plate 15a and having a plurality of slits 15b1 formed therein. The slit plate 15a is an example of a first slit plate, and the slits 15a1 are an example of slits formed in the first slit plate. The slit plate 15b is an example of a second slit plate, and the slits 15b1 are an example of slits formed in the second slit plate.

An outer edge portion of the slit plate 15 is held by the inner wall of the processing container 12 in a circumferential direction, and the slit plate 15 is configured to partition the plasma generation space U and the plasma processing space S. The slits 15a1 are staggered from the slits 15b1 in a reverse direction of a tilting direction (see FIG. 3) of the mounting surface 11a of the support structure 11. The slits 15a1 and the slits 15b1 do not overlap each other in a plan view.

The side wall of the processing container 12 in the plasma generation space U above the slit plate 15a is covered with a cylindrical quartz member 18. The insulating property of the quartz member 18 prevents the plasma generated in the space U from being drawn into the grounded processing container 12 and disappearing.

The controller Cnt is, for example, a computer including a processor, a memory, an input device, a display device, and the like. The controller Cnt operates according to a program based on a recipe input thereto and transmits control signals. Individual components of the tilt precleaning apparatus 10 are controlled by the control signals from the controller Cnt.

Hereinafter, each of the support structure 11, the gas supply 14, and a structure for holding the shield plate 13 will be described in detail.

### [Support Structure]

As shown in FIG. 3, the support structure 11 mounts the substrate W on the tilted mounting surface 11a thereof, and supports the substrate W so that the substrate W can be rotated at a predetermined tilt angle in the vertical direction. FIG. 1 shows a cross-sectional view of the support structure 11 seen from a Y direction, and FIG. 3 shows a cross-sectional view of the support structure 11 seen from an X direction. As shown in FIGS. 1 and 3, the support structure 11 includes a holder 30, a container 40, and the inclined shaft part 50.

The holder 30 is a mechanism for holding the substrate W and rotating the substrate W in a horizontal direction by being rotated about the second axis AX2. As described above, the second axis AX2 coincides with the axis PX when the support structure 11 is not tilted. The holder 30 includes the electrostatic chuck 31, a lower electrode 32, and a rotary shaft 33.

The electrostatic chuck 31 holds the substrate W on the mounting surface 11a, which is the upper surface of the electrostatic chuck 31. The electrostatic chuck 31 has a substantially disk shape with the second axis AX2 serving as a central axis thereof and includes an electrode film provided as an inner layer of an insulating film. The electrostatic chuck 31 generates an electrostatic force by applying a voltage to the electrode film. By virtue of the electrostatic force, the electrostatic chuck 31 electrostatically attracts the substrate W mounted on the mounting surface 11a. A heat transfer gas such as He gas or Ar gas is supplied to a space between the electrostatic chuck 31 and the substrate W. In addition, a heater for heating the substrate W may be built in the electrostatic chuck 31. The electrostatic chuck 31 is provided on the lower electrode 32.

Referring to FIGS. 1 and 2, the lower electrode 32 has a substantially disk shape with the second axis AX2 serving as a central axis thereof. The lower electrode 32 is made of a conductor such as aluminum or the like. The lower electrode 32 is electrically connected to the bias power supply 62. The electrostatic chuck 31 is provided with a coolant flow path. A temperature of the substrate W is controlled by supplying a coolant to the coolant flow path.

The rotary shaft 33 has a substantially cylindrical shape and is coupled to a lower surface of the lower electrode 32 at the center thereof. A central axis of the rotary shaft 33 coincides with the second axis AX2. The holder 30 is rotated by applying a rotational force to the rotary shaft 33.

The holder 30 having the configuration described above forms the support structure 11 together with the container 40. A through-hole through which the rotary shaft 33 passes is formed at the center of the container 40. A magnetic fluid seal 104 is provided between the container 40 and the rotary shaft 33. The magnetic fluid seal 104 airtightly seals the internal space of the support structure 11. The internal space of the support structure 11 is maintained at atmospheric pressure and is separated from the vacuum space S by the magnetic fluid seal.

Further, the internal structure of the container 40 will be described in detail with reference to FIG. 2. FIG. 2 is a diagram showing an example of the internal structure of the container 40 shown in FIG. 1. A rotary joint (rotary coolant joint) 102 for supplying a coolant to a coolant flow path 101 is disposed on an outer periphery of the rotary shaft 33 about the rotary shaft 33. The coolant is supplied from the coolant flow path 101 to a flow path 31a in the electrostatic chuck 31. A hollow cylindrical lower electrode holder 103 is disposed on the outer periphery of the rotary joint 102. Further, the magnetic fluid seal 104 for sealing the vacuum space S in the processing container 12 from the atmospheric space in the container 40 is disposed on an outer periphery of the lower electrode holder 103. By disposing the rotary joint 102 inside the magnetic fluid seal 104 as described above, it is not necessary to extend the rotary shaft 33 in a direction of the axis AX2 for arranging the rotary joint 102. As a result, a length of the container 40 in the direction of the axis AX2 can be shortened. Therefore, the support structure 11 can be tilted greatly without increasing an internal volume of the processing container 12. Therefore, it is possible to reduce a footprint.

A slip ring 105 for supplying electric power to a chuck electrode 31b and a heater 31c of the electrostatic chuck 31 and applying a bias voltage is disposed below the rotary joint 102. A motor 106 for rotating the rotary shaft 33 and a lift mechanism 107, which includes lift pins 107a for lifting the substrate W up and down from the holder 30, are disposed in a space between an outer periphery of the magnetic fluid seal 104 and the inner wall of the container 40. Further, a gas line 108 for supplying a backside gas to a back surface of the substrate W may be appropriately provided on the rotary shaft 33 and the lower electrode holder 103.

Referring back to FIG. 1, inner end portions of the inclined shaft part 50 are fit into openings formed in the container 40. The inclined shaft part 50 is offset with respect to a height of the substrate W until it reaches the processing container 12. As a result, the first axis AX1 is flush with the substrate W, and the center of the substrate W is located on the second axis AX2 even when the container 40 is tilted at a certain angle. Thus, it is possible to have a margin of process controllability. Further, as shown in FIG. 1, the inclined shaft part 50 extends to the outside of the processing container 12. The drive device 24 is coupled to one outer end portion of the inclined shaft part 50.

The drive device 24 pivotally supports the one outer end portion of the inclined shaft part 50. When the inclined shaft part 50 is rotated by the drive device 24, the support structure 11 is rotated vertically about the first axis AX1. As a result, the support structure 11 is inclined with respect to the axis PX. For example, the support structure 11 may be tilted so that the second axis AX2 forms an angle within 0 to 90 degrees with respect to the axis PX.

Wirings for various electric systems, a pipe for the heat transfer gas, and a pipe for the coolant pass through an inner hole of the inclined shaft part 50. These wirings and pipes are connected to the rotary shaft 33.

As shown in FIG. 2, the rotation motor 106 is provided in the internal space of the support structure 11. The rotation motor 106 generates a driving force for rotating the rotary shaft 33. In one embodiment, the rotation motor 106 is provided on a lateral side of the rotary shaft 33. The rotation motor 106 is connected via a transmission belt to a pulley attached to the rotary shaft 33. As a result, the rotational driving force of the rotation motor 106 is transmitted to the rotary shaft 33, and the holder 30 is rotated horizontally about the second axis AX2. A rotation speed of the holder 30 is, for example, in a range of 48 rpm or less. For example, the holder 30 is rotated at a rotation speed of 20 rpm during a process. A wiring for supplying electric power to the rotation motor 106 is drawn out to the outside of the processing container 12 through the inner hole of the inclined shaft part 50, and is connected to a motor power source provided outside the processing container 12.

As described above, the support structure 11 may include various mechanisms provided in the internal space that can be maintained at atmospheric pressure. Further, the support structure 11 is configured to draw the wirings or the pipes, which connect mechanisms accommodated in the internal space of the support structure 11 and devices such as a power source, a gas source, and a chiller unit provided outside the processing container 12, to the outside of the processing container 12. In addition to the wirings and the pipes described above, a wiring for connecting a heater power source provided outside the processing container 12 and a heater provided in the electrostatic chuck 31 may be drawn out from the internal space of the support structure 11 to the outside of the processing container 12 via the inner hole of the inclined shaft part 50.

### [Gas Supply System]

Next, a gas supply system will be described with reference to FIG. 4 showing the A-A cross section in FIG. 1. The gas supply 14 is connected to a gas introduction pipe 14c. The gas introduction pipe 14c is branched and connected to a flow path 14c1 and a flow path 14c2 formed inside the inner wall of the processing container 12. The flow path 14c1 and the flow path 14c2 extend in opposite directions along a circumferential direction to form a semicircular shape. End portions of the flow path 14c1 and the flow path 14c2 are respectively connected at substantially right angles to the flow path 14a and the flow path 14b which extend radially inward.

The flow path 14a branches into a flow path 14a1 and a flow path 14a2 which are formed along the circumferential direction inside the quartz member 18 covering the inner wall of the processing container 12. Gas holes 22a, 22b, 22c, and 22d are formed in the flow path 14a1 and the flow path 14a2 at equal intervals toward the center of the processing container 12.

The flow path 14b is branched into a flow path 14b1 and a flow path 14b2 which are formed along the circumferential direction inside the quartz member 18 on the opposite side of the flow path 14a1 and the flow path 14a2. Gas holes 22e, 22f, 22g, and 22h are formed in the flow path 14b1 and the flow path 14b2 at equal intervals toward the center of the processing container 12. While being separated from each other in the vertical direction, the flow paths 14a1 and 14a2 and the flow paths 14b1 and 14b2 are formed in a substantially ring shape on the same circumference. The eight gas holes 22a, 22b, 22c, 22d, 22e, 22f, 22g, and 22h (hereinafter collectively referred to as “gas holes 22”) are arranged at equal intervals.

With this configuration, the gas supply 14 introduces the processing gas into the gas generation space U from the eight gas holes 22 arranged at equal intervals. The processing gas evenly introduced into the processing container 12 from the eight gas holes 22 is plasmarized by the RF power introduced from the ICP source unit 16 via the radio frequency antenna 53, whereby plasma can be generated in the space U without being unevenly distributed. The number of gas holes is not limited to eight. A plurality of gas holes may be provided at equal intervals in the circumferential direction with respect to the axis PX.

The gas supply 14 may include one or more gas sources, one or more flow rate controllers, and one or more valves. Therefore, a flow rate of the processing gas from one or more gas sources of the gas supply 14 can be adjusted. The flow rate of the processing gas from the gas supply 14 and a timing of supplying the processing gas are individually adjusted by the controller Cnt.

### [Shield Plate Holding Structure]

Next, the structure for holding the shield plate 13 will be described with reference to FIG. 5. An outer edge portion (outer peripheral portion) of the shield plate 13 is held between the processing container 12 and a ring-shaped clamp 25, which is provided on a stepped portion formed on the side wall of the processing container 12, via an elastic body 23. The elastic body 23 is a spiral cushioning member disposed between a lower surface of the outer edge portion of the shield plate 13 and the stepped portion formed on the side wall of the processing container 12. The elastic body 23 may be composed of, for example, a metallic spiral ring.

The shield plate 13 is repeatedly expanded and contracted by heat of the plasma generated in the space U. As a result, tensile stress and compressive stress are applied to the shield plate 13. However, in the structure for holding the shield plate 13 of the present embodiment, the outer edge portion of the shield plate 13 can move between the clamp 25 and the elastic body 23. Therefore, the shield plate 13 has a structure in which damage such as cracking or the like due to the aforementioned stresses does not occur.

### [Shield Structure]

Next, a problem that may occur when conductive by-products generated by etching the substrate W adhere to the dielectric window 19, which is a window for introducing radio frequency (RF) power and serves as a vacuum partition, will be described. When a metallic film is formed on the dielectric window 19, radio frequency power cannot pass through the dielectric window 19 due to the metallic film. In addition, the radio frequency power is absorbed by the metallic film formed on the dielectric window 19 and is converted into heat. This causes eddy current heating, which leads to a decrease in an amount of radio frequency power introduced and a risk that the dielectric window 19 is cracked due to thermal stresses. Therefore, the dielectric window 19 on which the metallic film is formed needs to be replaced regularly.

When a shield structure using the slit plate 15 and the shield plate 13 is specialized for preventing adhesion of the by-products to the dielectric window 19 in order to solve the problem described above, supply of ions required for etching the substrate W may be hindered by the slit plate 15 and an etching rate may decrease. Therefore, it is desirable to efficiently draw the ions in the plasma toward the substrate W to etch the substrate W. That is, it is important to provide a structure capable of maintaining both the function of preventing adhesion of the by-products to the dielectric window 19 and the function of drawing ions.

In view of this, one embodiment provides a shield structure in which the shield plate 13 is disposed directly below the dielectric window 19 serving as a vacuum partition wall (i.e., disposed on the vacuum side) and two slit plates 15 are disposed between the plasma generation space U and the substrate W. Further, in the shield structure, the slits 15a1 and 15b1 of the two slit plates 15a and 15b are staggered so that the plasma generation space U cannot be directly and vertically seen from a side of the substrate W through the slits. Thus, it is possible to prevent the by-products generated during the etching from adhering to the dielectric window 19 as a metallic film.

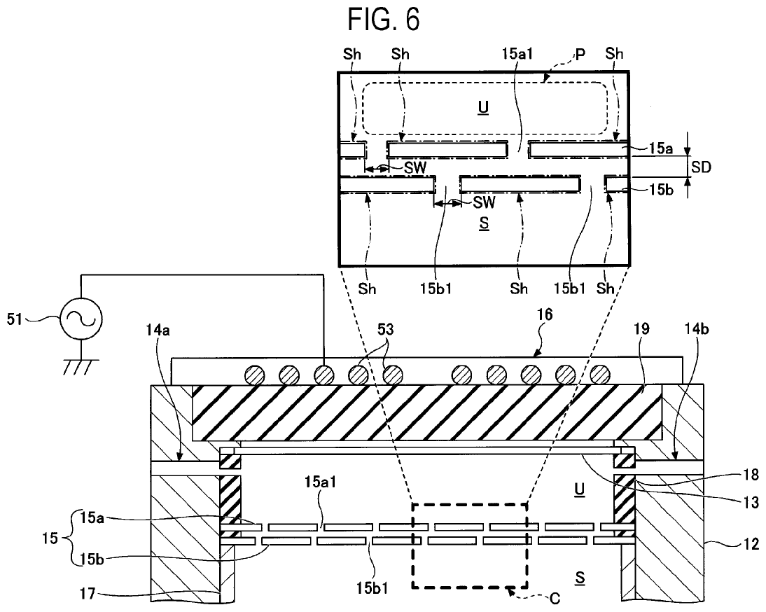

As a slit width (SW in FIG. 6) of the slit plates 15a and 15b decreases, the effect of preventing adhesion of the by-products to the dielectric window 19 increases. However, the supply of ions to the substrate W is hindered and the etching rate decreases. Therefore, in the present embodiment, the width and positions of the slits 15a1 and 15b1 of the slit plates 15a and 15b are optimized. Thus, it is possible to enhance the effect of preventing adhesion of the by-products to the dielectric window 19 and prevent a decrease in the etching rate.

In particular, the support structure 11 for mounting the substrate W thereon has a function of controlling the rotation and the tilt angle. Therefore, the support structure 11 can tilt the substrate W within a range of 0 to 90 degrees and can appropriately adjust a positional relationship between the slits 15a1 and the slits 15b1. As a result, it is possible to implement a shield structure that secures the number of ions drawn out from the plasma generation space U and reduces a passing amount of etching by-products from the substrate W. Hereinafter, the shield structure according to the present embodiment will be described in more detail.

### [Slit Plate]

As shown in a lower part of FIG. 6 which enlarges an upper part of the processing container 12 of FIG. 1, the slit plate 15 is composed of two plates, i.e., the upper slit plate 15a and the lower slit plate 15b. The positions of the slits 15a1 and 15b1 are staggered. That is, the slits 15a1 and the slits 15b1 have a positional relationship in which they do not overlap with each other in a plan view. The positional relationship in which the slits 15a1 and 15b1 are staggered will be hereinafter also referred to as “offset.”

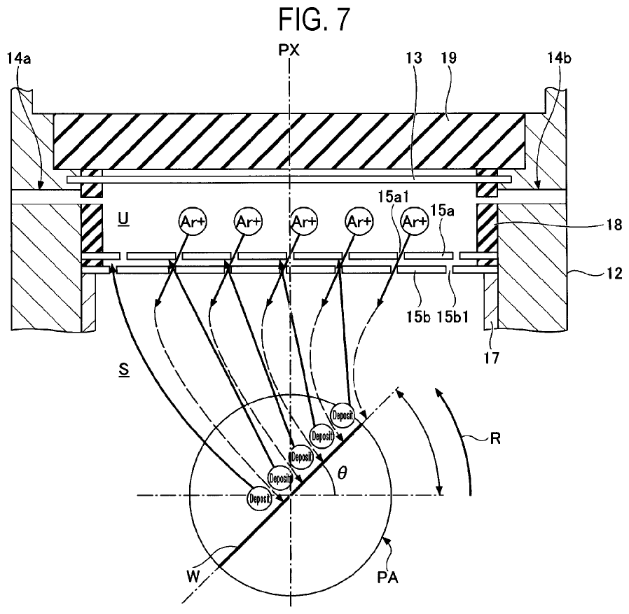

The tilt precleaning apparatus 10 has a structure in which the rotation of the substrate W and the tilt angle of the mounting surface 11a can be controlled by the support structure 11. The tilt angle of the mounting surface 11a is adjusted within a range of 0 degrees to 90 degrees. In the example of FIG. 7, the tilt angle of the mounting surface 11a is adjusted to 45 degrees. By controlling the rotation of the substrate W and the tilt angle of the mounting surface 11a by the support structure 11 and adjusting the width and positions of the slits 15a1 and 15b1 of the slit plates 15a and 15b as described above in combination, it is possible to secure both the adhesion prevention performance and the etching rate. Further, by disposing the shield plate 13 directly below the dielectric window 19, it is possible to suppress the adhesion of by-products to the dielectric window 19 serving as a window for introducing radio frequency power and to achieve freedom of maintenance for the dielectric window 19, thereby improving maintainability.

Adjustment of the width and positions of the slits 15a1 and 15b1 of the slit plates 15a and 15b will be specifically described with reference to FIG. 7. FIG. 7 is a diagram for explaining the width and positions of the slits 15a1 and 15b1 and movement of ions and by-products (deposits) due to the etching according to the embodiment. As shown in FIG. 7, ionized argon ions (Art) in the plasma generation space U above the slit plates 15 are drawn toward the substrate W through the slits 15a1 and 15b1. It is important to secure an etching rate that satisfies a process condition by action of argon ions. In addition, it is important to prevent the deposits from flying into the space U through the slits 15a1 and 15b1 and adhering to the dielectric window 19. As such, both (prevention of adhesion of the by-products to the dielectric window 19 or the like and implantation of argon ions into the substrate W) having a trade-off relationship co-exist. Therefore, in the present embodiment, inclination of the substrate W (mounting surface 11a) by the support structure 11 and offset of the slits 15a1 and 15b1 are combined. The argon ions are an example of ions, and the type of ions is not limited thereto. The type of ions varies depending on the type of gas supplied from the gas supply 14.

An offset direction of the slits 15a1 and 15b1 is important to establish the positional relationship of the offset slits 15a1 and 15b1, which facilitates drawing out the argon ions required for etching from the space U and makes it difficult to see the shield plate 13 directly from the inclined substrate W.

Thus, the offset direction of the slits 15a1 and 15b1 is optimized by utilizing the fact that the substrate W is tilted only in a specific direction. For example, in the example of FIG. 7, the substrate W is rotated about the axis PX in a state in which the substrate W is tilted obliquely leftward and upward (in FIG. 7, at an angle of θ=45 degrees with respect to the horizontal direction) about the axis PX. A rotation direction at that time is indicated by arrow R, and a rotation trajectory of an outer edge of the substrate W (having a diameter of, for example, 200 mm) is indicated by circle PA.

By offsetting the positions of the slits 15a1 and 15b1 of the two slit plates 15a and 15b with respect to the inclination of the substrate W, argon ions can easily reach the substrate W through the two slit plates 15a and 15b. Therefore, a position of each slit 15a1 is shifted in the rotation direction of the support structure 11 from a center position between two slits 15b1 adjacent to the slit 15a1. In other words, each slit 15a1 is shifted in the direction in which the substrate W is tilted (here, the left direction) from the center position between two slits 15b1 adjacent to the slit 15a1. As a result, the argon ions generated in the space U are easily incident into the plasma processing space S by passing through the slits 15a1 offset with respect to the slits 15b1 and then passing through the slits 15b1. The argon ions are incident into the space S obliquely leftward and downward due to the offset between the slits 15a1 and 15b1, and move radially. Thus, the argon ions are easily incident onto the substrate W tilted obliquely leftward and upward. The etching rate is determined by the number of ions drawn from the space U toward the substrate W through the slits 15a1 and 15b1. According to the configuration described above, by an appropriate offset positional relationship among the slits 15a1 and 15b1, the number of argon ions incident into the space S can be increased and the etching rate can be increased.

The deposits, which are generated at the time of etching by the implantation of the argon ions into the substrate W, fly toward the inner wall such as the ceiling and the side wall of the processing container 12. However, by using the fact that the substrate W is tilted in a specific direction, the slits 15a1 are offset with respect to the slits 15b1 in a direction that makes it difficult to see the dielectric window 19 from a side of the substrate W. Therefore, most of the deposits flying toward the ceiling in the space S adhere to a lower surface of the slit plate 15b, or pass through the slits 15b1 and adhere to a lower surface of the slit plate 15a. As a result, it is possible to prevent the deposits from adhering to the dielectric window 19 and forming a metallic film on the dielectric window 19.

As described above, the position of each slit 15a1 is shifted in the rotation direction of the support structure 11 from the center position between two slits 15b1 adjacent to the slit 15a1. That is, the slits 15a1 and the slits 15b1 are offset to positions where argon ions are easily sputtered on the surface of the substrate W and it is difficult for the deposits to pass through the slits 15a1 and 15b1. As a result, it is possible to suppress adhesion of the by-products formed by etching to the dielectric window 19 for introducing radio frequency power, while efficiently etching the substrate W.

An upper part of FIG. 6 shows, on an enlarged scale, a region enclosed by frame C in the lower part of FIG. 6. By optimizing the positions of the slits 15a1 and 15b1 offset from one another, it is possible to provide a structure in which a metallic film of the deposits generated when performing etching on the substrate W does not heavily adhere to the shield plate 13 and the dielectric window 19.

A distance between the lower surface of the slit plate 15a and an upper surface of the slit plate 15b is defined as “SD,” and the width of the slits 15a1 and the slits 15b1 is defined as “SW.” The width of the slits 15a1 and the width of the slits 15b1 are the same. When the slit width SW is increased, argon ions easily pass through the slits 15a1 and 15b1 and the etching rate increases. However, the effect of preventing adhesion of the by-products to the dielectric window 19 decreases. As the distance between the slits 15a1 and the slits 15b1 increases, the etching rate is decreased, but the effect of preventing adhesion of the by-products to the dielectric window 19 is enhanced.

As shown in the upper part of FIG. 6, while plasma is being generated, ion sheaths Sh are generated on the surfaces of the quartz slit plates 15a and 15b. When the argon ions make contact with the sheaths while moving between the slit plates 15a and 15b, the argon ions disappear. As the distance SD between the slit plates 15a and 15b decreases, a probability that the ions will collide with the slit plates increases. Thus, the number of disappearing argon ions increases and the etching rate decreases.

The interval among the slits 15a1 and the interval among the slits 15b1 may or may not be the same pitch, respectively. Further, the slits 15a1 and 15b1 are disposed so that longitudinal directions thereof become the same. That is, the slits 15a1 of the upper slit plate 15a and the corresponding slits 15b1 of the lower slit plate 15b are shifted by the same amount.

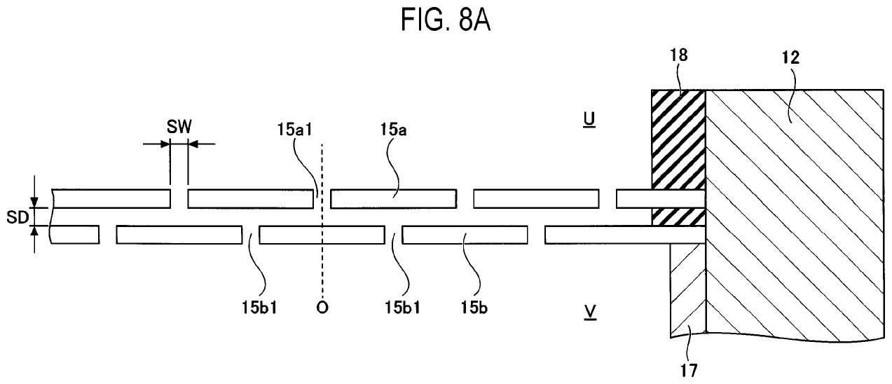

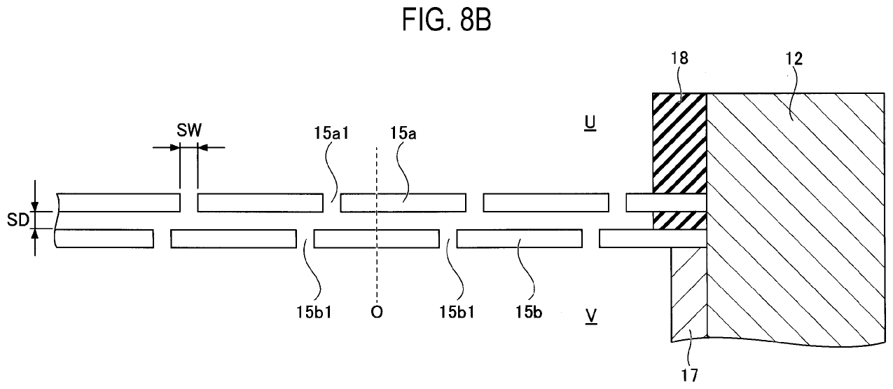

A simulation was performed to obtain an appropriate offset value between the slits 15a1 and 15b1. The appropriate offset value between the slits 15a1 and 15b1 will be described with reference to FIGS. 8A and 8B. FIGS. 8A and 8B are diagrams showing examples of a simulation for optimizing the positions of the slits according to an embodiment.

A simulation condition is as follows.

Slit plates: two upper and lower disks having a diameter φ of 150 mm

Width SW of slits: 8.5 mm

Thickness of each slit plate: 5 mm

Distance SD between the slit plates: 8.5 mm

In FIG. 8A, a position of each slit 15a1 is not shifted in the rotation direction of the support structure 11 from a central axis O between adjacent slits 15b1. In other words, the position of each slit 15a1 is not shifted in the direction in which the substrate W is tilted (the left direction in FIG. 7) from the central axis O between the slits 15b1 adjacent to the slit 15a1.

In contrast, in FIG. 8B, a position of each slit 15a1 is shifted in the rotation direction of the support structure 11 from the central axis O between adjacent slits 15b1. In other words, the position of each slit 15a1 is shifted in the direction in which the substrate W is tilted (the left direction in FIG. 7) from the central axis O between the slits 15b1 adjacent to the slit 15a1.

Simulation results of etching six substrates W (200 mm wafers) were obtained for the case of the offset shown in FIG. 8A and the case of the offset shown in FIG. 8B, respectively. As a result, in the case of the offset shown in FIG. 8B, there was a variation of 2.62 to 2.95% in an in-plane distribution of the etching of each of the six substrates W. On the other hand, in the case of the offset shown in FIG. 8A, the in-plane distribution of the etching of the six substrates W became non-uniform and the etching rate decreased, compared to the case of the offset shown in FIG. 8B.

From the above, it can be recognized that it is appropriate to set the offset value so that the position of each slit 15a1 is shifted in the rotation direction of the support structure 11 (the tilting direction indicated by the tilt angle θ in FIG. 7) from the center position between slits 15b1 adjacent to the slit 15a1. Thus, when the substrate W is tilted obliquely leftward and upward as shown in FIG. 7, the positions of the slits 15a1 with respect to the slits 15b1 are shifted to the left, which is the rotation direction, from the center positions between the slits 15b1. From this, an appropriate positional relationship between offsets of the slits 15a1 and 15b1 can be established, the number of argon ions incident into the space S can be increased, and the etching rate can be increased. In addition, since the substrate W is inclined obliquely leftward and upward, the slits 15a1 and 15b1 are offset to the positions where it is difficult for the deposits to pass through the slits 15a1 and 15b1. As a result, it is possible to prevent the by-products generated by the etching from adhering to the dielectric window 19 while efficiently etching the substrate W.

### [Modification]

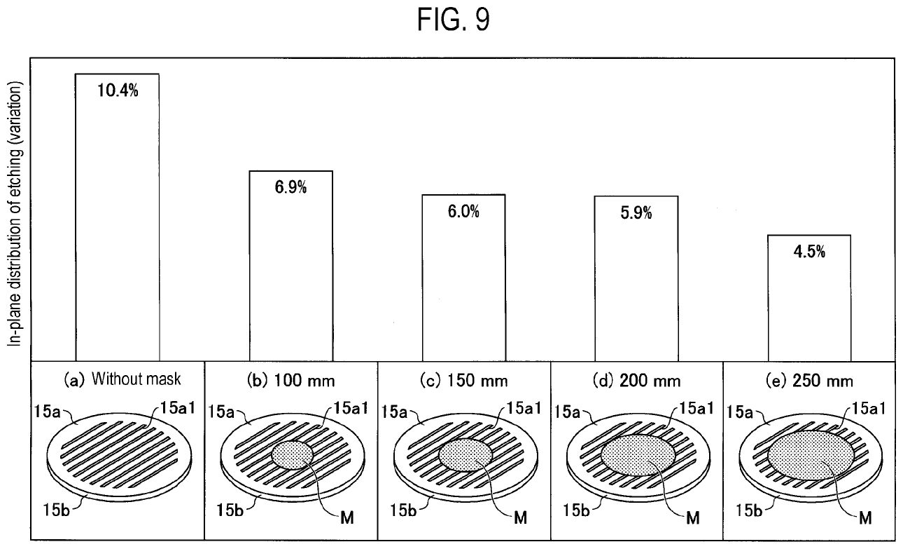

A plasma distribution has a high density at a center portion above the substrate W. In order to obtain a good etching distribution, it is important to have a structure for performing a uniform gas supply to the plasma generation space U and controlling ion distribution on the substrate W. Therefore, next, a slit plate 15 according to a modification of the embodiment will be described with reference to FIG. 9. FIG. 9 is a diagram showing an example of simulation results for optimizing masking of the slits 15a1 and 15b1 according to the modification of the embodiment.

In the above embodiment, as shown in the slit plate 15a of “Without mask” in (a) of FIG. 9, the slits 15a1 and 15b1 are formed at equal intervals over the entire surfaces of the slit plates 15a and 15b. In FIG. 9, the slits 15b1 below the slit plate 15a are not shown.

In contrast, in the slit plate 15 according to the modification of one embodiment, a central portion of the slit plate 15 is masked, by focusing on the fact that plasma is easily formed on the center side of the substrate W and a plasma density is likely to be higher on the center side of the substrate W than on the outer peripheral side thereof. Specifically, as shown in (b) to (e) of FIG. 9, the slits 15a1 and 15b1 are not opened at center portions of the slit plates 15a and 15b in order to spread the plasma, and are disposed only on outer peripheral portions of the slit plates 15a and 15b. That is, the slits 15a1 and 15b1 located at the center portions of the slit plates 15a and 15b are closed by a mask M, whereby ions in the plasma are supplied into the space S via the slits 15a1 and 15b1 opened at the outer peripheral portions of the slit plates 15a and 15b. As a result, it is possible to prevent the ions implanted into the substrate W from concentrating at the center portion of the substrate W, and it is possible to reduce variation in in-plane distribution of the etching.

A simulation condition when etching the substrate W having a diameter of 200 mm is as follows.

Slit plates: two upper and lower disks having a diameter φ of 400 mm

Width SW of slits: 8.5 mm

Thickness of each slit plate: 5 mm

Distance SD between the slit plates: 8.5 mm

A bar graph of FIG. 9 shows a degree of variation in in-plane distribution of the etching with respect to the presence/absence and size of the mask M provided on the slit plates 15a and 15b.

In FIG. 9, (a) shows that variation in in-plane distribution of etching when the etching is performed based on the argon ions, which are drawn out from the slits 15a1 and 15b1 of the slit plates 15a and 15b without providing the mask M, is 10.4%.

In FIG. 9, (b) to (e) show variations in in-plane distribution of etching when the etching is performed based on the argon ions, which are drawn out when a predetermined region from the centers of the slits 15a1 and 15b1 of the slit plates 15a and 15b is covered with the mask M. The mask M in (b) of FIG. 9 is a circular member having a diameter of 100 mm. The mask M in (c) of FIG. 9 is a circular member having a diameter of 150 mm. The mask M in (d) of FIG. 9 is a circular member having a diameter of 200 mm. The mask M in (e) of FIG. 9 is a circular member having a diameter of 250 mm

As a result, when the predetermined region from the centers of the slit plates 15a and 15b is covered with the mask M, the variation in in-plane distribution of the etching is 4.5% to 6.9%, which is smaller than when the mask M is not provided. Further, it can be recognized that the variation in in-plane distribution of the etching decreases as the mask M is enlarged.

However, as the mask M is enlarged, the number of ions reaching the substrate W decreases, which leads to a decrease in the etching rate. Therefore, an appropriate size of the mask M is 60 to 90% of the size of the substrate W. With such a size, it is possible to maintain the etching rate of the substrate W while reducing variation in in-plane distribution of the etching. Both of the two slit plates 15a and 15b may not be masked, as long as at least one of them is masked.

According to the configuration described above, by blocking the slits at the central portion with the mask M, it is possible to spread the plasma generated by the ICP source unit 16 that has a high density at the central portion and thereby reduce the variation in in-plane distribution of the etching. By combining such a configuration with the support structure 11 having the function of rotating and tilting the substrate W, it is possible to secure a good in-plane distribution of etching.

Further, it is desirable that the region masked by the mask M is a circular region having a diameter within a range of 60% to 90% from the center with respect to the diameter of the substrate W mounted on the mounting surface 11a. With such a configuration, the etching rate can be maintained while reducing the variation in in-plane distribution of the etching.

The tilt precleaning apparatus 10 may be used for cleaning the inside of the processing container 12 before film formation. In addition, the tilt precleaning apparatus 10 may be used to remove oxides on the substrate W between film formation of one film and film formation of a subsequent film, or may be used to make a formed film thin and flat.

The tilt precleaning apparatus 10 has a high vacuum degree (10⁻⁸ Torr to 10⁻⁹ Torr) when performing plasma processing. Thus, if the inside of the processing container 12 is changed once from a vacuum state to an atmospheric state at the time of maintenance, it takes time to create a vacuum state when processing a subsequent substrate W. Therefore, the shields 17, 21, and 26 disposed in the processing container 12 are provided with a function of depositing the by-products generated by etching for a certain period of time while maintaining the process performance, and maintenance (shield replacement) is performed simultaneously with maintenance of other processing apparatus in order to minimize a downtime of the apparatus.

In such a situation, since the tilt precleaning apparatus 10 has the shield structure using the slit plate 15 and the shield plate 13, it is possible to prevent the by-products generated by etching from adhering to the dielectric window 19 while efficiently etching the substrate W.

It should be appreciated that the plasma processing apparatuses according to the embodiment and the modification disclosed herein are exemplary in all respects and not limitative. The above embodiments can be modified and improved in various forms without departing from the scope of the appended claims and the gist thereof. The matters described in the plurality of embodiments may have other configurations within a consistent range and may be combined within a consistent range.

This international application claims priority based on Japanese Patent Application No. 2019-168888 filed on Sep. 17, 2019, and priority based on Japanese Patent Application No. 2020-74978 filed on Apr. 20, 2020, the entire contents of which are incorporated herein by reference.

### EXPLANATION OF REFERENCE NUMERALS

10: tilt precleaning apparatus, 11: support structure, 12: processing container, 13: shield plate, 14: gas supply, 15: slit plate, 15a: slit plate, 15a1: slit, 15b: slit plate, 15b1: slit, 16: ICP source unit, 17, 21, 26: shield, 18: quartz member, 19: dielectric window, 25: clamp, 30: holder, 31: electrostatic chuck, 32: lower electrode, 33: rotary shaft, 40: container, 50: inclined shaft part, 51: radio frequency power source, 53: radio frequency antenna, 102: rotary joint, 103: lower electrode holder, 104: magnetic fluid seal, 105: slip ring, 106: rotation motor, 107: lift mechanism, S: plasma processing space, U: plasma generation space

1. A plasma processing apparatus for performing plasma processing on a substrate, the plasma processing apparatus comprising:
a plasma generator configured to generate plasma in a processing container;
a support structure configured to mount the substrate on a tilted mounting surface in the processing container and rotatably support the substrate;
a first slit plate made of quartz and provided between the plasma generator and the support structure, the first slit plate having first slits formed in the first slit plate; and
a second slit plate made of quartz and provided between the plasma generator and the support structure and below the first slit plate, the second slit plate having second slits formed in the second slit plate,
wherein the first slits are staggered from adjacent ones of the second slits in a reverse direction of a tilting direction of the mounting surface.

2. The plasma processing apparatus of claim 1, wherein positions of the first slits are shifted in a rotation direction of the support structure from a central axis between two adjacent second slits.

3. The plasma processing apparatus of claim 2, wherein the first slits and the second slits do not overlap with each other in a plan view.

4. The plasma processing apparatus of claim 3, wherein at least one selected from the group of the first slit plate and the second slit plate is masked radially from a center of each of the first slit plate and the second slit plate.

5. The plasma processing apparatus of claim 4, wherein the at least one selected from the group of the first slit plate and the second slit plate is masked in a circular region having a diameter in a range of 60% to 90% from the center with respect to a diameter of the substrate mounted on the mounting surface.

6. The plasma processing apparatus of claim 5, wherein the plasma generator includes a radio frequency antenna, and
a shield plate made of quartz is disposed below a dielectric window that transmits radio frequency power supplied from the radio frequency antenna.

7. The plasma processing apparatus of claim 6, wherein the shield plate has an outer edge portion held between a clamp provided on a stepped portion formed on a side wall of the processing container and an elastic body.

8. The plasma processing apparatus of claim 7, wherein the side wall of the processing container forming a plasma generation space above the first slit plate is covered with a cylindrical quartz member.

9. The plasma processing apparatus of claim 8, wherein the plasma generator includes a gas supply configured to supply a gas, and
wherein the gas supply is configured to introduce the gas into the plasma generation space from a plurality of gas holes provided at equal intervals on a side wall of the quartz member.

10. The plasma processing apparatus of claim 9, wherein a magnetic fluid seal for sealing an inside of the processing container from a space inside a container of the support structure is provided inside the container of the support structure, and
wherein a rotary joint is disposed inside the magnetic fluid seal.

11. The plasma processing apparatus of claim 1, wherein the first slits and the second slits do not overlap with each other in a plan view.

12. The plasma processing apparatus of claim 1, wherein at least one selected from the group of the first slit plate and the second slit plate is masked radially from a center of each of the first slit plate and the second slit plate.

13. The plasma processing apparatus of claim 1, wherein the plasma generator includes a radio frequency antenna, and
a shield plate made of quartz is disposed below a dielectric window that transmits radio frequency power supplied from the radio frequency antenna.

14. The plasma processing apparatus of claim 1, wherein a side wall of the processing container forming a plasma generation space above the first slit plate is covered with a cylindrical quartz member.

15. The plasma processing apparatus of claim 1, wherein a magnetic fluid seal for sealing an inside of the processing container from a space inside a container of the support structure is provided inside the container of the support structure, and
wherein a rotary joint is disposed inside the magnetic fluid seal.
